(19) United States
(12) Patent Application Publication
(10) Pub. No.: US 2014/0203293 A1
(43) Pub. Date: Jul. 24, 2014

(54) NITRIDE SEMICONDUCTOR LIGHT EMITTING DEVICE

(71) Applicant: SAMSUNG ELECTRONICS CO., LTD., Suwon-si (KR)

(72) Inventors: Kyung Wook HWANG, Hwaseong-si (KR); Jung Sub KIM, Hwaseong-si (KR); Jae Hyeok HEO, Seogwipo-si (KR)

(73) Assignee: SAMSUNG ELECTRONICS CO., LTD., Suwon-si (KR)

(21) Appl. No.: 14/161,361

(22) Filed: Jan. 22, 2014

(30) Foreign Application Priority Data
Jan. 24, 2013 (KR) 10-2013-0008312

(51) Int. Cl. H01L 33/10; H01L 33/32

(52) U.S. Cl. CPC H01L 33/10; H01L 33/32
USPC 257/76; 257/98; 438/29

(57) ABSTRACT

A nitride semiconductor light emitting device includes a substrate, a multi-layer structure, a light-transmitting concave-convex structure and a light emitting structure. The multi-layer structure has layers of a first layer and a second layer such that the first and second layers have different refractive indexes and are alternately stacked. The concave-convex structure is disposed in an upper surface of the multi-layer structure and includes a light-transmitting material. The light emitting structure is disposed on the multi-layer structure and includes a first conductive semiconductor layer, an active layer, and a second conductive semiconductor layer.

### CROSS-REFERENCE TO RELATED APPLICATION

This application claims benefit of priority to Korean Patent Application No. 10-2013-0008312, filed on Jan. 24, 2013 in the Korean Intellectual Property Office, the entire contents of which are hereby incorporated by reference.

### TECHNICAL FIELD

The present inventive concept relates to a nitride semiconductor light emitting device and a method of manufacturing the same.

### BACKGROUND

A semiconductor light emitting device such as a light emitting diode (LED) is a device capable of generating light from materials included therein, through the conversion of energy generated by the recombination of electrons and holes in a p-n semiconductor junction, into light. LEDs have been widely used in illumination devices, display devices and light sources, and the development thereof has therefore tended to be accelerated.

In particular, in recent times, since the development of gallium nitride-based LEDs used in commercialized products, such as mobile phone keyboards, side mirror turn signals for vehicles, camera flashes, has been accelerated, the development of general illumination devices using light emitting diodes has been actively undertaken. As the application of LEDs has broadened from relatively small products to relatively large products, in application products thereof such as backlight units for a large sized television sets, vehicle headlights, general illumination devices, or the like, LEDs have also been developed as highly-efficient high-output products. Therefore, light sources capable of exhibiting properties required by corresponding products have been demanded.

As the range of a use of a semiconductor light emitting device increases, a method for improving light extraction efficiency of a semiconductor light emitting device is required.

### SUMMARY

An aspect of the present inventive concept provides a nitride semiconductor light emitting device having improved light extraction efficiency.

An aspect of the present inventive concept relates to a nitride semiconductor light emitting device including a substrate, a multi-layer structure having layers of a first layer and a second layer such that the first and second layers have different refractive indexes and are alternately stacked, a light-transmitting concave-convex structure disposed in an upper surface of the multi-layer structure and including a light-transmitting material, and a light emitting structure disposed on the multi-layer structure and including a first conductive semiconductor layer, an active layer, and a second conductive semiconductor layer.

The light-transmitting concave-convex structure may include a plurality of protrusions spaced apart from one another in the upper surface of the multi-layer structure.

The light-transmitting material may be a material selected from SiOₓ, SiNₓ, Al₂O₃, HfO, TiO₂, ZrO, or alloys thereof.

The light-transmitting concave-convex structure may have one of a dome shape, a cylindrical shape, a polygonal pillar shape, a conic shape, and a polygonal pyramid shape.

The light-transmitting concave-convex structure may include a light-transmitting material layer disposed on the multi-layer structure and including a plurality of recess parts.

The light-transmitting material layer may be a porous nitride layer.

The light-transmitting material layer may have a smaller refractive index than a refractive index value of the nitride single crystal layer of the multi-layer structure contacting the light-transmitting material layer.

The recess part may include an intaglio pattern having one of a dome shape, a cylindrical shape, a polygonal pillar shape, a conic shape, and a polygonal pyramid shape.

The multi-layer structure may further include a third layer having a refractive index different from refractive indexes of the first and second layers.

The first conductive semiconductor layer may include a plurality of nanocores, and the active layer and the second conductive semiconductor layer are sequentially stacked on the nanocores.

The multi-layer structure may be a distributed brag reflector (DBR) structure.

The first and second layers may include porous GaN layers having different degrees of pore density.

The first and second layers may include n-GaN layers having different doping concentrations.

Another aspect of the present inventive concept encompasses a nitride semiconductor light emitting device including a substrate, a multi-layer structure disposed on the substrate and including an upper surface in which nitride single crystal layers of a first layer and a second layer having different refractive indexes are alternately stacked and a plurality of recess parts are defined, and alight emitting structure disposed on the multi-layer structure and including a first conductive semiconductor layer, an active layer, and a second conductive semiconductor layer.

The recess part may be defined in an upper portion of the multi-layer structure.

Still another aspect of the present inventive concept relates to a method of manufacturing nitride semiconductor light emitting device. The method includes forming a silicon substrate. A multi-layer structure is formed to have nitride single crystal layers of a first layer and a second layer, such that the first and second layers have different refractive indexes and are alternately stacked. A light-transmitting concave-convex structure is formed in an upper surface of the multi-layer structure. The light-transmitting concave-convex structure includes a light-transmitting material. A light emitting structure is formed on the multi-layer structure.

The forming of the light-transmitting concave-convex structure may include forming a plurality of protrusions spaced apart from one another in the upper surface of the multi-layer structure.

The forming of the light-transmitting concave-convex structure may include forming a light-transmitting material layer on the multi-layer structure, and forming a plurality of recess parts in the light-transmitting concave-convex structure.

The forming of the light emitting structure may include forming of a first conductive semiconductor layer, forming a plurality of nanocores in the first conductive semiconductor layer, and sequentially stacking an active layer and a second conductive semiconductor layer on the nanocores.

The first and second layers may include porous GaN layers having different degrees of pore density.

### BRIEF DESCRIPTION OF THE DRAWINGS

The above and other aspects, features and other advantages of the present inventive concept will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIG. 1 is a side cross-sectional view of a nitride semiconductor light emitting device according to an embodiment of the present inventive concept.

FIGS. 2 to 4 are cross-sectional views illustrating respective main processes of a method of manufacturing the nitride semiconductor light emitting device of FIG. 1.

FIG. 5 schematically illustrates a path of light in the nitride semiconductor light emitting device of FIG. 1.

FIG. 6 is a side cross-sectional view illustrating another example of a nitride semiconductor light emitting device according to an embodiment of the present inventive concept.

FIG. 7 is a side cross-sectional view of a nitride semiconductor light emitting device according to another embodiment of the present inventive concept.

FIG. 8 is a side cross-sectional view of a nitride semiconductor light emitting device according to another embodiment of the present inventive concept.

FIG. 9 is a side cross-sectional view illustrating another example of the nitride semiconductor light emitting device according to an embodiment of the present inventive concept.

FIGS. 10A to 10E illustrate various examples of a concave-convex structure, which can be employed in the nitride semiconductor light emitting device of FIG. 1.

FIGS. 11A and 11B are simulation graphs for comparing amounts of light reflected when angles of incident light are 0°, 15° and 30°, respectively.

### DETAILED DESCRIPTION

Embodiments of the present inventive concept will now be described in detail with reference to the accompanying drawings.

The present inventive concept may, however, be embodied in many different forms and should not be construed as being limited to embodiments set forth herein. Rather, these embodiments of the present inventive concept are provided so that this disclosure will be thorough and complete, and will fully convey the scope of the present inventive concept to those skilled in the art.

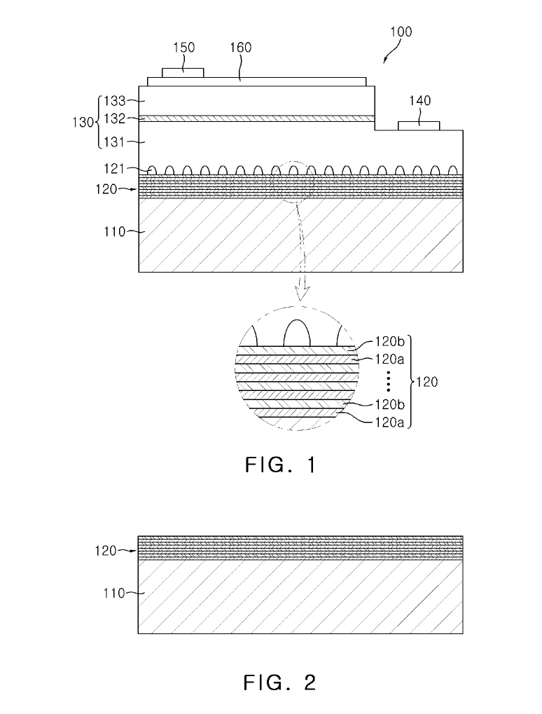

FIG. 1 is a side cross-sectional view of a nitride semiconductor light emitting device according to an embodiment of the present inventive concept. FIGS. 2 to 4 are cross-sectional views illustrating respective main processes of a method of manufacturing the nitride semiconductor light emitting device of FIG. 1. FIG. 5 schematically illustrates a path of light in the nitride semiconductor light emitting device of FIG. 1.

As illustrated in FIG. 1, a nitride semiconductor light emitting device 100 may include a substrate 110, a multi-layer structure 120, a concave-convex structure including protrusions 121, and a light emitting structure 130.

The substrate 110 may be a wafer for fabrication of the nitride semiconductor light emitting device 100. The substrate 110 may be formed using silicon (Si), sapphire, silicon carbide (SiC), MgAl₂O₄, MgO, LiAlO₂, LiGaO₂, gallium nitride (GaN), or the like. In an embodiment of the present inventive concept, a silicon substrate may be used.

When a silicon substrate is used, the possibility of the occurrence of a defect due to a difference in a lattice constant between silicon (Si) and gallium nitride (GaN) may be increased. When the Si substrate is used, since stress exerted thereon should be controlled to suppress bending thereof, while simultaneously restraining the occurrence of defects, a buffer layer (not separately shown) having a composite structure may be used.

Explaining an example of the buffer layer having the composite structure as described above, AlN may first be formed on the substrate 110. Here, a material not containing gallium (Ga) may be used to prevent a reaction of Si with Ga. A material such as SiC or the like may be used as well as AlN. AlN formed on the substrate 110 may be grown at a temperature of 400 to 1300° C. using an Al source and an N source. An intermediate AlGaN layer may be interposed between a plurality of AlN layers to control the stress in GaN as needed.

The light emitting structure 130 may include a first conductive semiconductor layer 131, a second conductive semiconductor layer 133, and an active layer 132 interposed therebetween. Although it is not particularly limited, in an embodiment of the present inventive concept, the first and second conductive semiconductor layers 131 and 133 may be an n-type semiconductor layer and a p-type semiconductor layer, respectively. The first and second conductive semiconductor layers 131 and 133 may be formed of a material forming, for example, a nitride semiconductor. In this case, the material may be a material such as GaN, AlGaN, InGaN, or the like, represented by a compositional formula of AlₓIn_{y}Ga_{(1-x-y)}N (0≦x≦1, 0≦y≦1, 0≦x+y≦1).

The active layer 132 may emit light having a predetermined wavelength by the recombination of electrons provided from the first or second conductive semiconductor layer 131 or 133 and holes provided from the second or first conductive semiconductor layers 133 or 131. The active layer 132 may have a single quantum well (SQW) or a multiple quantum well (MQW) structure in which a quantum well layer and a quantum barrier layer are alternately stacked. In the case of the MQW structure, for example, an InGaN/GaN structure may be used.

The first and second conductive semiconductor layers 131 and 133 and the active layer 132 may be grown by using a semiconductor growth process, such as metal organic chemical vapor deposition (MOCVD), molecular beam epitaxy (MBE), hydride vapor phase epitaxy (HVPE), or the like.

In an embodiment of the present inventive concept, light generated in the active layer 132 may be emitted omnidirectionally, and light directed toward the silicon substrate 110 may not be extracted to the outside as a considerable amount of the light may be absorbed by the silicon substrate 110 to thus be lost.

In order to solve such a brightness deterioration problem, an embodiment of the present inventive concept may employ a reflective structure in which light directed toward the silicon substrate 110 is redirected.

In an embodiment of the present inventive concept, the multi-layer structure 120 having a reflective structure may be formed on the silicon substrate 110. The multi-layer structure 120 may have a structure in which nitride single crystal layers of a first layer 120a and a second layer 120b having different refractive indexes are alternately stacked.

For example, a distributed brag reflector (DBR) structure may be provided by appropriately adjusting a refractive index and a thickness of the first layer 120a and the second layer 120b.

Here, the first and second layers 120a and 120b of the multi-layer structure 120 may be formed to have a thickness of λ/4n when a wavelength generated in the active layer 132 is defined as λ and n is defined as a refractive index of a corresponding layer, and may have a thickness of approximately 300 Å to 900 Å. In this case, in the multi-layer structure 120, the refractive indexes and the thicknesses of the first and second layers 120a and 120b may be selectively designed to have a relatively high reflective index, for example, 95% or more, with respect to a wavelength of light generated in the active layer 132.

The refractive indexes of the first and second layers 120a and 120b may be determined within a range of 1.4 to 2.5. Although the refractive indexes of the first and second layers 120a and 120b may have a value less than the refractive index of the first conductive semiconductor layer 131 and the refractive index of the silicon substrate 110, the refractive indexes of the first and second layers 120a and 120b may have a value less than a refractive index of the first conductive semiconductor layer 131 but greater than an refractive index of the silicon substrate 110.

Although the nitride single crystal forming the first and second layers 120a and 120b of the multi-layer structure 120 may be obtained by selectively and alternately stacking layers of aluminium gallium nitride (AlGaN) and gallium nitride (GaN), the nitride single crystal forming the first and second layers 120a and 120b may be obtained by stacking porous GaN layers having different degrees of pore density and may also be obtained by alternately stacking n-GaN layers having different doping concentrations.

In addition, the multi-layer structure 120 may further include third to n-th layers (n is a natural number of 4 or more) having different refractive indexes. Respective layers configuring the multi-layer structure 120 may have the same or different thicknesses.

Since the multi-layer structure 120 has the structure in which the nitride single crystal layers are stacked, epitaxial layers for forming a necessary light emitting structure 130 thereon may be grown.

A concave-convex structure formed of a light-transmitting material may be formed on an upper surface of the multi-layer structure 120. In an embodiment of the present inventive concept, as the concave-convex structure, the protrusions 121 may be employed.

In order for the reflective structure having the multi-layer structure 120 to allow light directed toward the silicon substrate 110 in the active layer 132 to be redirected, the light should be incident to a surface of the multi-layer structure 120 at a predetermined angle. However, the angle is limited to an angle of light incident in a normal direction perpendicular to the surface of the multi-layer structure 120 or an angle of light incident with respect to a normal line at an angle within 15 degrees.

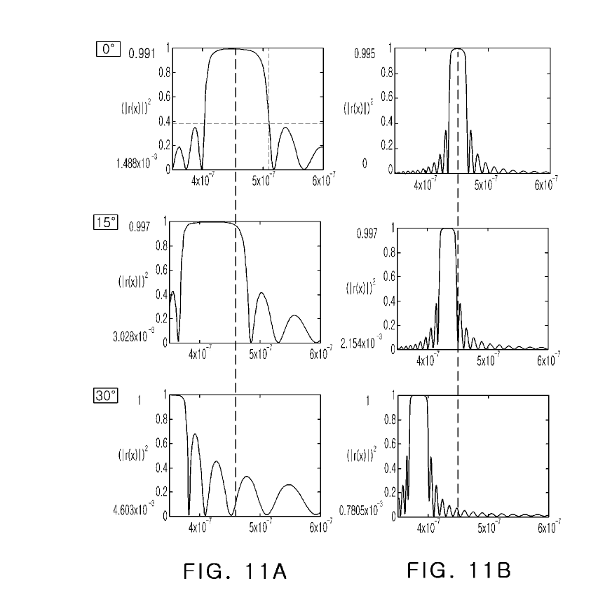

FIGS. 11A and 11B are simulation graphs for comparing amounts of light reflected when an angle of incident light is 0°, 15° and 30°, respectively. FIG. 11A illustrates a case in which the refractive indexes of the first layer 120a and the second layer 120b of the multi-layer structure 120 are 2 and 1.5, respectively, and 11 layers are alternately stacked. FIG. 11B illustrates a case in which the refractive indexes of the first layer 120a and the second layer 120b of the multi-layer structure 120 are 2.5 and 2.3, respectively, and 20 layers are alternately stacked. A wavelength of light in both of the cases is 450 nm. In both graphs, it can be appreciated that a relatively high reflectivity, 95% or more, is shown when angles of incident light are 0 and 15 degrees, while a refractive index is rapidly reduced when an angle of incident light is 30 degrees.

Therefore, when an angle formed by incident light incident into the multi-layer structure 120 and a normal line of a surface of the multi-layer structure 120 exceeds 15 degrees, the incident light may not be reflected but may be transmitted through the multi-layer structure 120.

Thus, in order to improve the reflective efficiency of light in the multi-layer structure 120, there is a need to allow a greater amount of light to be incident with respect to the surface of the multi-layer structure 120 at an angle within 15 degrees.

The concave-convex structure formed in the upper surface of the multi-layer structure 120 may allow a greater amount of light to be reflected and redirected from the multi-layer structure 120 by compensating for an angle of incident light incident to the surface of the multi-layer structure 120.

The protrusions 121 may be formed of a light-transmitting material having a refractive index value lower than refractive indexes of the multi-layer structure 120 and the light emitting structure 130. In detail, the protrusions 121 may be formed of a transparent material selected from SiOₓ, SiNₓ, Al₂O₃, HfO, TiO₂, ZrO, ZnO, or alloys thereof. As described above, when the protrusions 121 are formed of a transparent material, a path of light may be compensated for without a loss of incident light. A path of light incident by a low refractive index characteristic may be compensated for to be relatively closer to a normal direction, e.g., a direction perpendicular to the surface of the multi-layer structure 120.

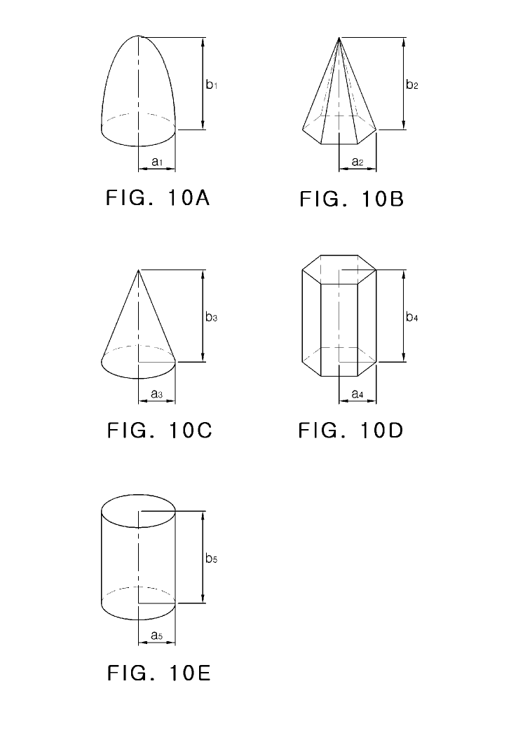

The protrusions 121 may be protruded from an upper surface of the multi-layer structure 120 at a predetermined interval therebetween. As shown in FIGS. 10A to 10E, the protrusions 121 may have various shapes, for example, a dome shape in FIG. 10A, a polygonal pyramid shape in FIG. 10B, a conic shape in FIG. 10C, a polygonal pillar shape in FIG. 10D, or a cylindrical shape in FIG. 10E. In this case, a ratio of a lower side (e.g., a₁, a₂, a₃, a₄ and a₅) and a height (e.g., b₁, b₂, b₃, b₄ and b₅) of the protrusion 121 may be variously applied.

With reference to FIG. 5, a path of light L1 penetrating the protrusions 121 according to an embodiment of the present inventive concept will be described in detail.

A process in which the path of light L1, among the light emitted in the active layer 132, incident on the surface of the multi-layer structure 120 at an angle of 15 degrees or above with respect to the normal direction of the surface, is compensated for, will be described with an example thereof.

The light directed toward the silicon substrate 110 may be incident through the protrusions 121 before reaching the multi-layer structure 120. Since the protrusions 121 are formed of a transparent material to have a lower refractive index than a refractive index of the first conductive semiconductor layer 131, the light is refracted toward the multi-layer structure 120. Therefore, as compared with the case in which the protrusions 121 are not formed, an angle of the incident light within the multi-layer structure 120 may be compensated for to be close to the normal direction of the surface of the multi-layer structure 120, and the amount of light reflected in the multi-layer structure 120 may be increased.

Subsequently, a method of manufacturing a nitride semiconductor light emitting device 100 as described above will be described with reference to FIGS. 1 to 4.

First, as shown in FIG. 2, the multi-layer structure 120 may be formed on the afore-described silicon substrate 110. Before forming the multi-layer structure 120, a buffer layer (not separately shown) may be further formed on the silicon substrate 110 in order to reduce the deterioration in a crystal lattice quality of the multi-layer structure 120 due to a difference in lattice constants and thermal expansion coefficients between the silicon substrate 110 and the multi-layer structure 120. In an embodiment of the present inventive concept, a nitride semiconductor may be used as the buffer layer.

The multi-layer structure 120 may be formed by alternately and repeatedly depositing nitride single crystal layers having different refractive indexes. In an embodiment of the present inventive concept, the multi-layer structure 120 may be obtained by repeatedly depositing AlGaN and GaN to grow epitaxial layers to allow for formation of the light emitting structure 130 to be formed thereon.

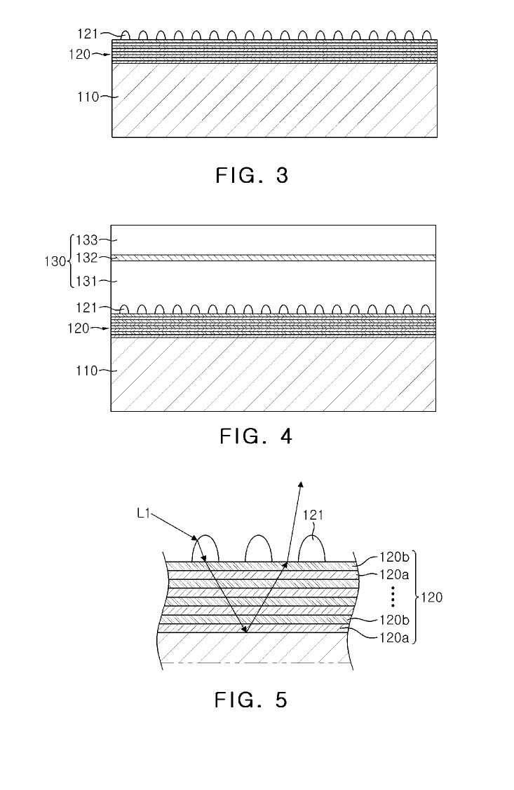

Then, as shown in FIG. 3, the protrusions 121 formed of a light-transmitting material may be formed on the multi-layer structure 120. The protrusions 121 may be spaced apart from one another such that the multi-layer structure 120 exposed between the protrusions 121 may be provided as a crystal face able to have an epitaxial layer for the formation of the light emitting structure 130 grown thereon.

The protrusions 121 may be formed through a process in which a light-transmitting material layer is formed on the multi-layer structure 120 and is then etched. A height of the protrusion 121 may be determined by controlling a thickness of the light-transmitting material layer and an etched depth. The lower side of the protrusion 121 may be determined by adjusting a shape of an etching mask formed on the light-transmitting material layer.

Next, as illustrated in FIG. 4, the first conductive semiconductor layer 131, the active layer 132 and the second conductive semiconductor layer 133 may be sequentially stacked to cover the multi-layer structure 120 in which the protrusions 121 have been formed, thereby forming the light emitting structure 130. In this case, the first conductive semiconductor layer 131 may be grown on the crystal face provided by the multi-layer structure 120 exposed between the protrusions 121, through an epitaxial lateral overgrowth (FLOG) process to cover the protrusions 121, whereby a potential of the first conductive semiconductor layer 131 may be reduced to enhance crystalline properties.

Then, as shown in FIG. 1, a portion of the light emitting structure 130 may be mesa etched to expose the first conductive semiconductor layer 131, and a first electrode 140 and a second electrode 150 may be respectively formed on the first and second conductive semiconductor layers 131 and 133. In addition, a transparent electrode layer 160 may be formed on the second conductive semiconductor layer 133. The transparent electrode layer 160 may be a transparent conductive oxide layer or nitride layer, and specifically, may be a layer of at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminium-doped zinc oxide (AZO), gallium-doped zinc oxide (GZO), In₄Sn₃O₁₂, or zinc magnesium oxide (Zn₍₁₋ₓ₎MgₓO) (0≦x≦1). Although an embodiment of the present inventive concept describes the case of an epi-up structure in which the first and second electrodes 140 and 150 are exposed to an upper surface of the light emitting structure 130 by way of example, the present inventive concept is not limited thereto and thus various variations may be provided.

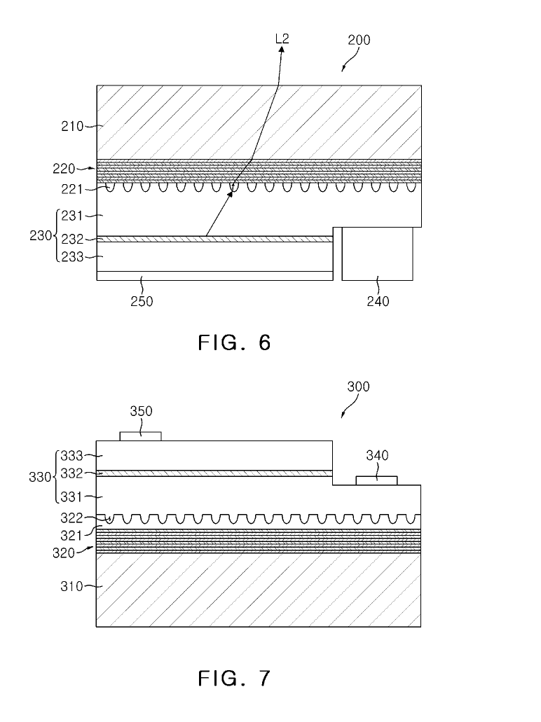

Subsequently, another example of the nitride semiconductor light emitting device according to an embodiment of the present inventive concept will be described. FIG. 6 is a side cross-sectional view illustrating another example of the nitride semiconductor light emitting device according to an embodiment of the present inventive concept.

With reference to FIG. 6, a nitride semiconductor light emitting device 200 according to another example of an embodiment of the present inventive concept may include a light-transmitting substrate 210, a multi-layer structure 220, a concave-convex structure 221, and a light emitting structure 230. The light emitting structure 230 may include a first conductive semiconductor layer 231, a second conductive semiconductor layer 233, and an active layer 232 interposed therebetween. A first electrode 240 and a second electrode 250 may be respectively formed on the first and second conductive semiconductor layers 231 and 233.

In an embodiment of the present inventive concept, a flip-chip structure in which light L2 emitted from the active layer 232 is emitted through the light-transmitting substrate 210 may be employed. Although the nitride semiconductor light emitting device 200 according to an embodiment of the present inventive concept may be understood to be similar to the structure of the nitride semiconductor light emitting device 100 shown in FIG. 1, the nitride semiconductor light emitting device 200 may have a difference from the nitride semiconductor light emitting device 100 shown in FIG. 1 in that it has a structure in which light is emitted through the light-transmitting substrate 210.

The substrate 210 may be a wafer for fabrication of the nitride semiconductor light emitting device 200. As the substrate 210, various substrates such as a sapphire substrate, a silicon (Si) substrate, a MgAl₂O₄ substrate, a MgO substrate, a LiAlO₂ substrate, a LiGaO₂ substrate, or the like, may be used. In an embodiment of the present inventive concept, the sapphire substrate may be used.

The multi-layer structure 220 may have a structure in which nitride single crystal layers having different refractive indexes are alternately stacked. Light having a specific direction may be incident into the substrate 210, as described above, by employing the plurality of layers having different refractive indexes therein. In addition, in the multi-layer structure 220, total internal reflection in an interface between the light-transmitting substrate 210 and the light emitting structure 230 may be reduced to thus improve light extraction efficiency.

The multi-layer structure 220 may include a material having light-transmitting properties to emit light emitted from the light emitting structure 230 to external matters, for example, the substrate, the surrounding atmosphere, or the like. For example, the multi-layer structure 220 may include a material selected from ZrN, CrN, ZrC, TiC, TaC, Ga₂O₃, Cr₂O₃, AlN, GaN, ZnO, or alloys thereof. In more detail, when GaN is used, the multi-layer structure 220 may include porous GaN.

Although the refractive index difference in the multi-layer structure 220 may be embodied by selectively and alternately stacking layers of materials forming the multi-layer structure 220, for example, ZrN, CrN, ZrC, TiC, TaC, Ga₂O₃, Cr₂O₃, AlN, GaN, ZnO, or the like, the refractive index difference may be obtained by stacking GaN layers having different porosities from one another in which different degrees of pore density are provided.

Therefore, since the multi-layer structure 220 as described above may allow light having a specific direction to be incident into the substrate 210, an amount of the light in which the light having been incident into the substrate 210 is reflected on the surface of the substrate 210 may be reduced.

Next, referring to FIG. 7, another embodiment of the present inventive concept will be described. FIG. 7 is a side cross-sectional view of a nitride semiconductor light emitting device according to another embodiment of the present inventive concept.

With reference to FIG. 7, a nitride semiconductor light emitting device 300 according to an embodiment of the present inventive concept may include a substrate 310, a multi-layer structure 320, a concave-convex structure configured of recess parts 322, and a light emitting structure 330. The light emitting structure 330 may include a first conductive semiconductor layer 331, a second conductive semiconductor layer 333, and an active layer 332 interposed therebetween. A first electrode 340 and a second electrode 350 may be respectively formed on the first and second conductive semiconductor layers 331 and 333.

Although the nitride semiconductor light emitting device 300 according to an embodiment of the present inventive concept may be understood to be similar to the structure of the nitride semiconductor light emitting device 100 shown in FIG. 1, the nitride semiconductor light emitting device 300 has a difference from the nitride semiconductor light emitting device 100 shown in FIG. 1 in that the concave-convex pattern is formed in the light-transmitting material layer 321 having the recess parts 322 formed therein.

The recess parts 322 may be used to compensate for a path of light in a similar manner to the nitride semiconductor light emitting device 100 shown in FIG. 1, while the recess parts 322 have a difference in that a concave shape is employed unlike FIG. 1.

As described above, when the recess parts 322 are formed in the light-transmitting material layer 321, since an effect similar to that of a concave lens may be exhibited, light in the active layer 332 directed toward the multi-layer structure 320 may be refracted toward the substrate 310 while passing through the recess parts 322. Thus, as compared with the case in which the recess parts 322 are not formed, an angle of the incident light within the multi-layer structure 320 may be compensated for to be close to the normal direction of the surface of the multi-layer structure 320, and the amount of light reflected in the multi-layer structure 320 may be increased. In addition, since the light is incident to be close to the normal direction of the surface of the multi-layer structure 320, even when the multi-layer structure 320 configured of a less amount of layers as compared to the related art is employed, the same effect may be obtained.

The light-transmitting material layer 321 may be formed of a transparent material, the material also allowing for the growth of an epitaxial layer for the formation of the light emitting structure 330 thereon. The light-transmitting material layer 321 may be formed of a porous nitride layer. When a GaN material is used, the light-transmitting material layer 321 may include porous GaN.

In this case, the light-transmitting material layer 321 may have a smaller refractive index than a refractive index of the nitride single crystal layer of the multi-layer structure 320, whereby an angle of incident light within the multi-layer structure 320 may be compensated for to be relatively closer to the normal direction of the surface of the multi-layer structure 320.

In addition, as shown in FIGS. 10A to 10E, the recess parts 322 may be formed of various shapes of intaglio patterns, for example, a dome shape in FIG. 10A, a polygonal pyramid shape in FIG. 10B, a conic shape in FIG. 10C, a polygonal pillar shape in FIG. 10D, or a cylindrical shape in FIG. 10E.

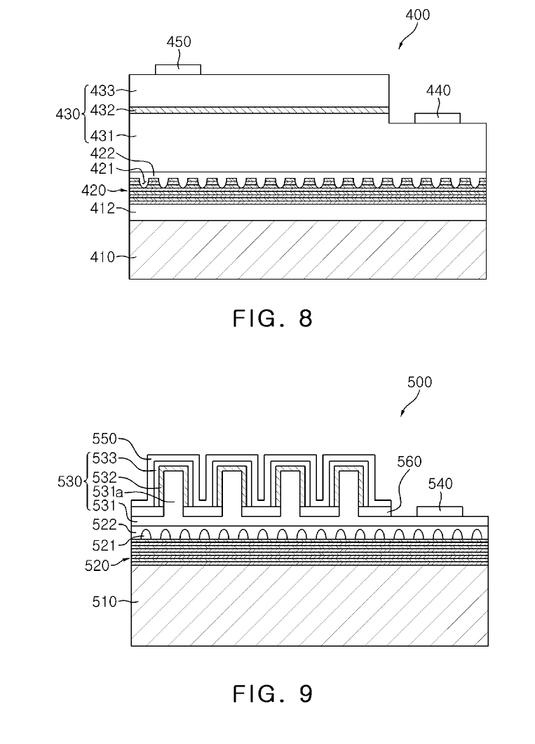

Then, another embodiment of the present inventive concept will be described with reference to FIG. 8. FIG. 8 is a side cross-sectional view of a nitride semiconductor light emitting device 400 according to another embodiment of the present inventive concept.

Referring to FIG. 8, the nitride semiconductor light emitting device 400 according to an embodiment of the present inventive concept may include a substrate 410, a multi-layer structure 420 having a recess part 421 formed therein, and alight emitting structure 430. The light emitting structure 430 may include a first conductive semiconductor layer 431, a second conductive semiconductor layer 433, and an active layer 432 interposed therebetween. A first electrode 440 and a second electrode 450 may be respectively formed on the first and second conductive semiconductor layers 431 and 433.

Although the nitride semiconductor light emitting device 400 according to an embodiment of the present inventive concept may be understood to be similar to the structure of the nitride semiconductor light emitting device 300 shown in FIG. 7, the nitride semiconductor light emitting device 400 may have a difference from the nitride semiconductor light emitting device 300 shown in FIG. 7 in that it has a structure in which the recess parts 421 are formed by etching an upper portion of the multi-layer structure 420, rather than forming the separate light-transmitting material layer 321 on the multi-layer structure 320 to form the recess parts 322 in the light-transmitting material layer 321 as illustrated in FIG. 7.

As such, the recess parts 421 may be formed by directly etching portions of the multi-layer structure 420, thereby resulting in a simplified process as compared with the process in which the separate material layer is formed on the multi-layer structure to form the recess parts therein.

In addition, in an embodiment of the present inventive concept, a buffer layer 412 may be formed in order to reduce the deterioration in crystal lattice qualities of the multi-layer structure 420 due to a difference in lattice constants and thermal expansion coefficients between the silicon substrate 410 and the multi-layer structure 420. In a similar manner thereto, a buffer layer 422 may also be formed between the light emitting structure 430 and the multi-layer structure 420.

Another exemplary embodiment of the present inventive concept will be described with reference to FIG. 9. FIG. 9 is a side cross-sectional view illustrating another example of the nitride semiconductor light emitting device according to an embodiment of the present inventive concept.

As illustrated in FIG. 9, a nitride semiconductor light emitting device 500 according to another exemplary embodiment of the present inventive concept may include a substrate 510, a multi-layer structure 520, a concave-convex structure including protrusions 521, and a light emitting structure 530. A buffer layer 522 may be formed between the light emitting structure 530 and the multi-layer structure 520.

Although the nitride semiconductor light emitting device 500 according to an embodiment of the present inventive concept may be understood to be similar to the structure of the nitride semiconductor light emitting device 100 shown in FIG. 1, the nitride semiconductor light emitting device 500 may have a difference from the nitride semiconductor light emitting device 100 shown in FIG. 1 in that it has a structure in which light emitting structures 530 configured of a plurality of nanostructures may be included therein.

A first conductive semiconductor layer 531 may include a nanocore between insulating patterns 560 having a protruding shape. An active layer 532 and a second conductive semiconductor layer 533 may be formed in a manner in which they surround the nanocore of the first conductive semiconductor layer 531. As shown in FIG. 9, the nanocore may have a nanorod shape, but this should not be considered to be limiting. That is, the nanocore may also have a pyramid shape.

As described in other embodiments above of the present inventive concept, the protrusions 521 may be replaced with recess parts, and in this case, the effects thereof are as described in the afore-mentioned embodiments of the present inventive concept.

The first conductive semiconductor layer 531 may include an exposed region on which a first electrode 540 is to be disposed. The first electrode 540 may be formed on the exposed region of the first conductive semiconductor layer 531. A second electrode 550 may be formed on the second conductive semiconductor layer 533. The second electrode 550 may be provided as a conductive layer encompassing the second conductive semiconductor layer 533. The second electrode 550 may be formed of a transparent conductive oxide layer or nitride layer such that light generated in the active layer 532 may be emitted upwardly, and specifically, may be formed of at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminium-doped zinc oxide (AZO), gallium-doped zinc oxide (GZO), In₄Sn₃O₁₂, or zinc magnesium oxide (Zn₍₁₋ₓ₎MgₓO) (0≦x≦1).

As set forth above, a nitride semiconductor light emitting device according to an embodiment of the present inventive concept may have relatively enhanced light extraction efficiency.

While the present inventive concept has been shown and described in connection with embodiments, it will be apparent to those skilled in the art that modifications and variations could be made without departing from the spirit and scope of the present inventive concept as defined by the appended claims.

What is claimed is:

1. A nitride semiconductor light emitting device, comprising:
a substrate;
a multi-layer structure having layers of a first layer and a second layer, such that the first and second layers have different refractive indexes and are alternately stacked;
a light-transmitting concave-convex structure disposed in an upper surface of the multi-layer structure and including a light-transmitting material; and
a light emitting structure disposed on the multi-layer structure and including a first conductive semiconductor layer, an active layer, and a second conductive semiconductor layer.

2. The nitride semiconductor light emitting device of claim 1, wherein the light-transmitting concave-convex structure includes a plurality of protrusions spaced apart from one another in the upper surface of the multi-layer structure.

3. The nitride semiconductor light emitting device of claim 2, wherein the light-transmitting material is a material selected from the group consisting of SiOₓ, SiNₓ, Al₂O₃, HfO, TiO₂, ZrO and alloys thereof.

4. The nitride semiconductor light emitting device of claim 2, wherein the light-transmitting concave-convex structure has one of a dome shape, a cylindrical shape, a polygonal pillar shape, a conic shape, and a polygonal pyramid shape.

5. The nitride semiconductor light emitting device of claim 1, wherein the light-transmitting concave-convex structure includes a light-transmitting material layer disposed on the multi-layer structure and including a plurality of recess parts.

6. The nitride semiconductor light emitting device of claim 5, wherein the light-transmitting material layer is a porous nitride layer.

7. The nitride semiconductor light emitting device of claim 5, wherein the light-transmitting material layer has a smaller refractive index than a refractive index value of the layer of the multi-layer structure contacting the light-transmitting material layer.

8. The nitride semiconductor light emitting device of claim 5, wherein the recess part includes an intaglio pattern having one of a dome shape, a cylindrical shape, a polygonal pillar shape, a conic shape, and a polygonal pyramid shape.

9. The nitride semiconductor light emitting device of claim 1, wherein the multi-layer structure further includes a third layer having a refractive index different from refractive indexes of the first and second layers.

10. The nitride semiconductor light emitting device of claim 1, wherein:
the first conductive semiconductor layer includes a plurality of nanocores, and
the active layer and the second conductive semiconductor layer are sequentially stacked on the nanocores.

11. The nitride semiconductor light emitting device of claim 1, wherein the multi-layer structure is a distributed brag reflector (DBR) structure.

12. The nitride semiconductor light emitting device of claim 1, wherein the first and second layers include porous GaN layers having different degrees of pore density.

13. The nitride semiconductor light emitting device of claim 1, wherein the first and second layers include n-GaN layers having different doping concentrations.

14. A nitride semiconductor light emitting device comprising:
a substrate;
a multi-layer structure disposed on the substrate and including an upper surface in which layers of a first layer and a second layer having different refractive indexes are alternately stacked and a plurality of recess parts are defined; and
a light emitting structure disposed on the multi-layer structure and including a first conductive semiconductor layer, an active layer, and a second conductive semiconductor layer.

15. The nitride semiconductor light emitting device of claim 14, wherein the recess part is defined in an upper portion of the multi-layer structure.

16. A method of manufacturing nitride semiconductor light emitting device, comprising steps of:
forming a silicon substrate;
forming a multi-layer structure to have layers of a first layer and a second layer, such that the first and second layers have different refractive indexes and are alternately stacked;
forming a light-transmitting concave-convex structure in an upper surface of the multi-layer structure the light-transmitting concave-convex structure including a light-transmitting material; and
forming a light emitting structure on the multi-layer structure.

17. The method of claim 16, wherein the step of forming the light-transmitting concave-convex structure includes forming a plurality of protrusions spaced apart from one another in the upper surface of the multi-layer structure.

18. The method of claim 16, wherein the step of forming the light-transmitting concave-convex structure includes:
forming a light-transmitting material layer on the multi-layer structure; and
forming a plurality of recess parts in the light-transmitting concave-convex structure.

19. The method of claim 16, wherein the step of forming the light emitting structure includes:
forming a first conductive semiconductor layer;
forming a plurality of nanocores in the first conductive semiconductor layer; and
sequentially stacking an active layer and a second conductive semiconductor layer on the nanocore.

20. The method of claim 16, wherein the first and second layers include porous GaN layers having different degrees of pore density.
